(19) United States
(12) Patent Application Publication
(10) Pub. No.: US 2007/0103705 A1
(43) Pub. Date: May 10, 2007

(54) COLOR CALIBRATION METHODS AND SYSTEMS FOR DIGITAL IMAGES

(75) Inventors: Jing Shun Lin, Yilan County (TW); Chao Lien Tsai, Taipei City (TW)

Correspondence Address: QUINTERO LAW OFFICE, PC, 2210 MAIN STREET, SUITE 200, SANTA MONICA, CA, 90405, US

(73) Assignee: BENQ CORPORATION, TAOYUAN (TW)

(21) Appl. No.: 11/557,881

(22) Filed: Nov. 8, 2006

(30) Foreign Application Priority Data
Nov. 9, 2005 (TW) TW94139259

(51) Int. Cl. G03F 3/08

(52) U.S. Cl. 358/1.9; 358/518; 358/406

(57) ABSTRACT

Color calibration methods for a digital image capture device are provided. Identification of a printer is first received. It is determined whether color information of the printer is stored in the digital image capture device. If so, the color information is sent from the digital image capture device to the printer for printing. If not, the digital image capture device converts hue value calibration data to acquire color related data for printing.

### BACKGROUND

The invention relates to color calibration methods, and in particular to color calibration methods for a digital image capture device.

This section is intended to introduce the reader to various aspects of art, which may be related to various aspects of the invention, which are described and/or claimed below. This discussion is intended to be helpful in providing the reader with background information to facilitate a better understanding of the various aspects of the invention. Accordingly, it should be understood that these statements are to be read in this light, and not as admissions of related art.

Digital image capturing technology is implemented in various devices, such as: digital cameras, digital video cameras, and portable communication devices implementing digital image capture devices (for example, mobile phones and personal digital assistants).

Images captured by a digital image capture device may be transmitted to a printing device via an image transmission protocol, such as PictBridge. PictBridge, an image transmission protocol, is used to transmit an image stored in a memory device of a digital image capture device to a printing device for printing. For example, after a digital camera captured a desired image, the captured image is stored in a memory card. The digital camera is linked to a printer conforming to PictBridge protocol via a USB (Universal Serial Bus) cable. The image stored in the memory card can be printed by the printer without processing by a photo editing software or a computer.

Digital cameras and printers vary, and use different RGB values. When images obtained from a digital camera are printed in a printer having RGB values different from the digital camera, the printing result may suffer from color inaccuracy and saturation deficiency.

### SUMMARY

Certain aspects commensurate in scope with the originally claimed invention are set forth below. It should be understood that these aspects are presented merely to provide the reader with a brief summary of certain forms the invention might take and that these aspects are not intended to limit the scope of the invention. Indeed, the invention may encompass a variety of aspects that may not be set forth below.

A method for color calibration of a digital image is provided, implemented in a digital image capture device. Identification information is received from a printer, wherein the printer is linked to the digital image capture device. It is determined whether color information of the printer is stored in the digital image capture device. The color information is transmitted to the printer if the color information of the printer is stored in the digital image capture device. Hue value calibration data is converted to obtain the color information if color information of the printer is not stored in the digital image capture device.

Also provided is a storage medium for storing a computer program providing the described method for color calibration of a digital image.

Also provided is a system for color calibration of a digital image, implemented in a digital image capture device. A receiving module, receives identification information of a printer, wherein the printer is coupled to the digital image capture device. An identifying module, coupling to the receiving module, determines whether color information of the printer is stored in the digital image capture device. A transmission module, coupling to the identifying module, transmits the color information to the printer if the color information of the printer is stored in the digital image capture device. A converting module, coupling to the identifying module, converts hue value calibration data to obtain the color information if color information of the printer is not stored in the digital image capture device.

### BRIEF DESCRIPTION OF DRAWINGS

The invention can be more fully understood by reading the subsequent detailed description and examples with references made to the accompanying drawings, wherein:

FIG.. 1 is a flowchart of an embodiment of a method for color calibration of a digital image.

FIG. 2 is a flowchart of an embodiment of the conversion step of FIG. 1;

FIG. 3 is a diagram of an embodiment of a storage medium for storing a computer program providing the method for color calibration of a digital image;

FIG. 4 is a schematic functional block diagram showing functional components of an embodiment of a system for color calibration of a digital image; and

FIG. 5 illustrates an embodiment of color calibration of a digital image.

### DETAILED DESCRIPTION

One or more specific embodiments of the invention are described in the following. In an effort to provide a concise description of these embodiments, not all features of an actual implementation are described in the specification. It should be appreciated that in the development of any such actual implementation, as in any engineering or design project, numerous implementation-specific decisions must be made to achieve specific goals of the developers, such as compliance with system-related and business-related constrains, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

the following detailed description, reference is made to the accompanying drawings which form a part hereof, shown by way of illustration of specific embodiments. These embodiments are described in sufficient detail to enable those skilled in the art to practice the invention, and it is to be understood that other embodiments may be utilized and that structural, logical and electrical changes may be made without departing from the spirit and scope of the present invention. The following detailed description is, therefore, not to be taken in a limiting sense. The leading digit(s) of reference numbers appearing in the figures corresponds to the Figure number, with the exception that the same reference number is used throughout to refer to an identical component which appears in multiple figures. It should be understood that the many of the elements described and illustrated throughout the specification are functional in nature and may be embodied in one or more physical entities or may take other forms beyond those described or depicted.

FIG. 1 is a flowchart of an embodiment of a method for color calibration of a digital image. According to this embodiment, a method for color calibration of a digital image is provided, and the method is implemented in a digital image capture device.

Identification information of a printer, is received (step S100), wherein the printer is coupled to the digital image capture device, and the identification information specifies the type of the printer. The digital image capture device and the printer are coupled according to PictBridge protocol.

It is determined whether color information of the printer is stored in the digital image capture device (step S102). The color information is a color calibration conversion matrix comprising conversion matrix coefficients for hue values (RGB values) of the printer and the digital image capture device.

If the color information of the printer is stored in the digital image capture device, the color information is transmitted to the printer (step S104) and used for printing (step S106). If color information of the printer is not stored in the digital image capture device, hue value calibration data is converted to obtain the color information (step S108).

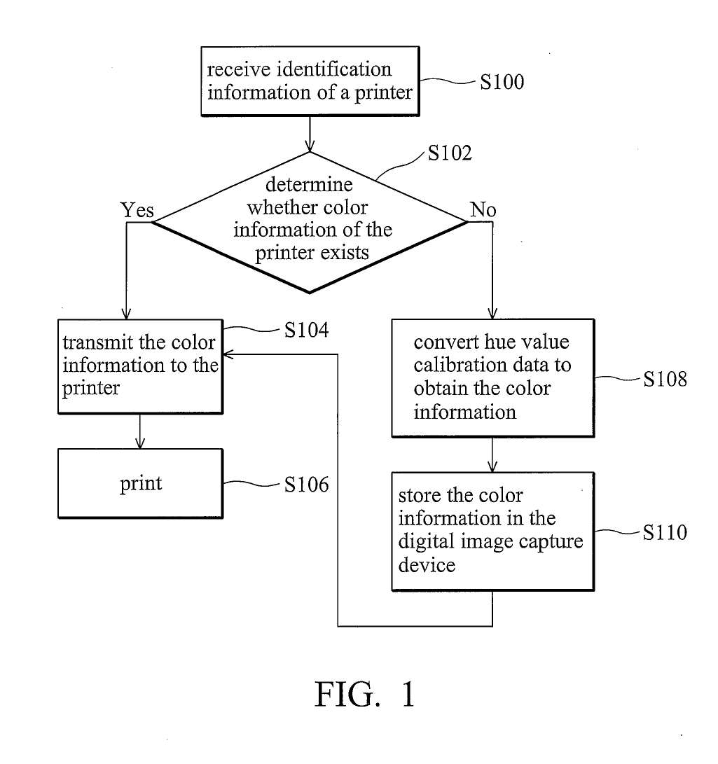

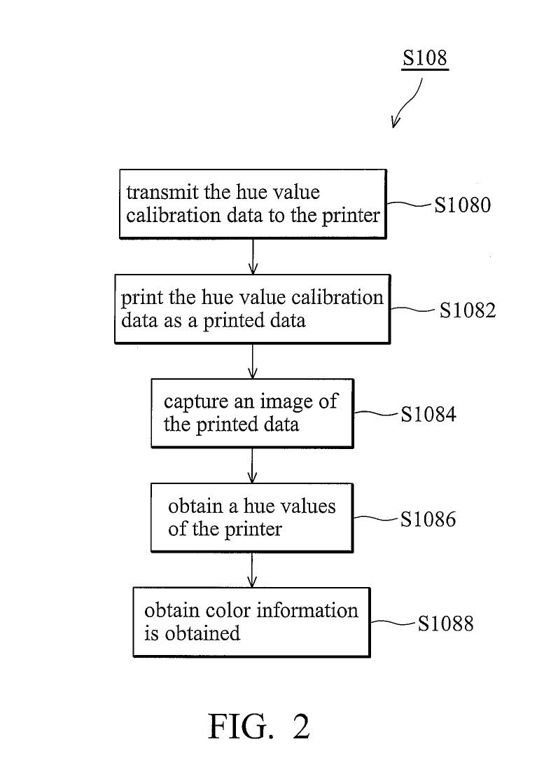

FIG. 2 is a flowchart of an embodiment of the conversion step of FIG. 1. The hue value calibration data may a Macbeth chart, or other data suitable as a calibration standard. The hue value calibration data can be stored in the printer or the digital image capture device. When the hue value calibration data is stored in the digital image capture device, the digital image capture device transmits the hue value calibration data to the printer (step S1080) The printer prints the hue value calibration data as printed data (step S1082). The digital image capture device captures an image of the printed data (step S1084).

The image is analyzed to obtain a hue values (RGB values) of the printer (step S1086). The color information is obtained according to the hue values of the printer and a hue value of the digital image capture device (step S1088) The color information is obtained according to the following equation:

$$[ \begin{matrix}R \\ G \\ B\end{matrix} ] = [ \begin{matrix}{a}_{11} & {a}_{12} & {a}_{13} \\ {a}_{21} & {a}_{22} & {a}_{23} \\ {a}_{31} & {a}_{32} & {a}_{33}\end{matrix} ] [ \begin{matrix}{R}_{1} \\ {G}_{1} \\ {B}_{1}\end{matrix} ] .$$

R′ G′ B are hue values of the printer, R₁′ G₁′ B₁ are hue values of the digital image capture device, a₁₁˜a₃₃ specify the color information. The obtained color information can be stored in the digital image capture device or transmitted to the printer for printing.

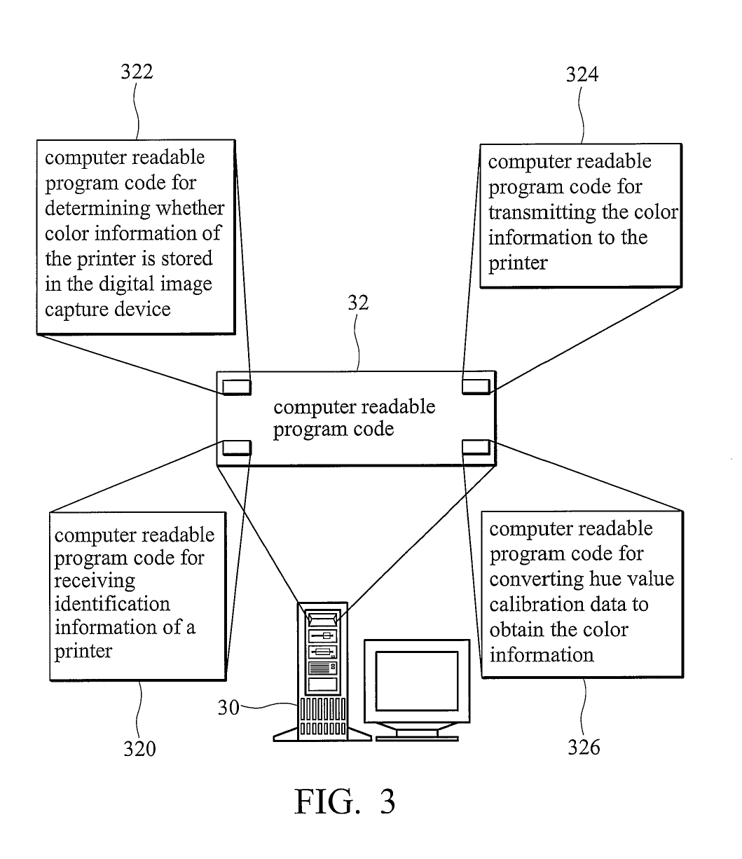

FIG. 3 is a diagram of an embodiment of a storage medium for storing a computer program providing the method for color calibration of a digital image. The computer program system comprises a computer usable storage medium 30 having computer readable program code 32 embodied in the medium, comprising computer readable program code 320 for receiving identification information of a printer, a computer readable program code 322 for determining whether color information of the printer is stored in the digital image capture device, a computer readable program code 324 for transmitting the color information to the printer, and a computer readable program code 326 for converting hue value calibration data to obtain the color information.

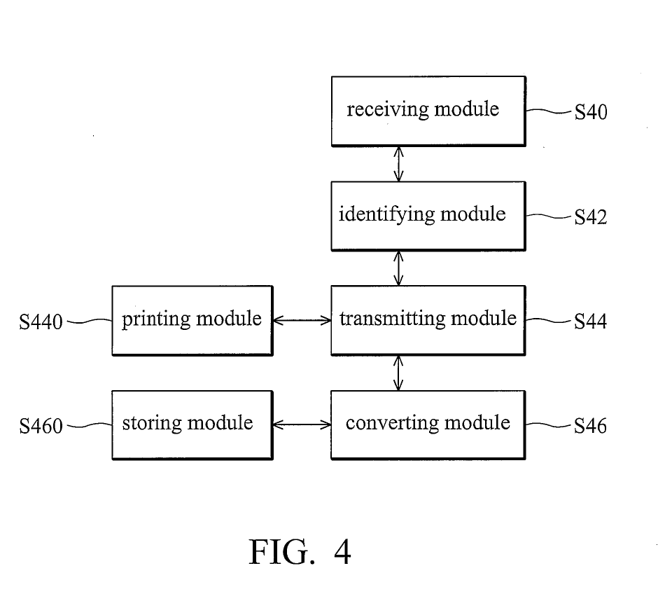

FIG. 4 is a schematic functional block diagram showing functional components of an embodiment of a system for color calibration of a digital image. According to this embodiment, a system for color calibration of a digital image is provided, and the system is implemented in a digital image capture device.

The system comprises a receiving module 40, an identifying module 42, a transmission module 44, and a converting module 46.

The receiving module 40 receives identification information of a printer, wherein the printer is coupled to the digital image capture device, wherein the printer is coupled to the digital image capture device, and the identification information specifies the type of printer. The digital image capture device and the printer are coupled according to PictBridge protocol.

The identifying module 42 determines whether color information of the printer is stored in the digital image capture device. The color information is a color calibration conversion matrix comprising conversion matrix coefficients for hue values (RGB values) of the printer and the digital image capture device.

The transmission module 44 transmits the color information to the printer if the color information of the printer is stored in the digital image capture device.

The converting module 46 converts the hue value calibration data to obtain the color information if color information of the printer is not stored in the digital image capture device. The hue value calibration data may a Macbeth chart, or other data suitable as a calibration standard.

The converting module further causes the digital image capture device to capture the printed data as an image, wherein the printed data is obtained by using the printer to print the hue value calibration data. The converting module further analyzes the image to obtain a hue value of the printer. The converting module further obtains the color information according to the hue value of the printer and a hue value of the digital image capture device.

The converting module further obtains the color information according to the following equation:

$$[ \begin{matrix}R \\ G \\ B\end{matrix} ] = [ \begin{matrix}{a}_{11} & {a}_{12} & {a}_{13} \\ {a}_{21} & {a}_{22} & {a}_{23} \\ {a}_{31} & {a}_{32} & {a}_{33}\end{matrix} ] [ \begin{matrix}{R}_{1} \\ {G}_{1} \\ {B}_{1}\end{matrix} ] .$$

R′ G′ B are hue values of the printer, R₁′ G₁′ B₁ are hue values of the digital image capture device, a₁₁˜a₃₃ specify the color information. The hue value calibration data can be stored in the printer or the digital image capture device. When the hue value calibration data is stored in the digital image capture device, the digital image capture device transmits the hue value calibration data to the printer.

The system for color calibration of a digital image further comprises a printing module 440 and a storage module 460. The printing module 440, coupling to the transmission module 44, prints using the color information. The storage module 460, coupling to the converting module, stores the color information in the digital image capture device.

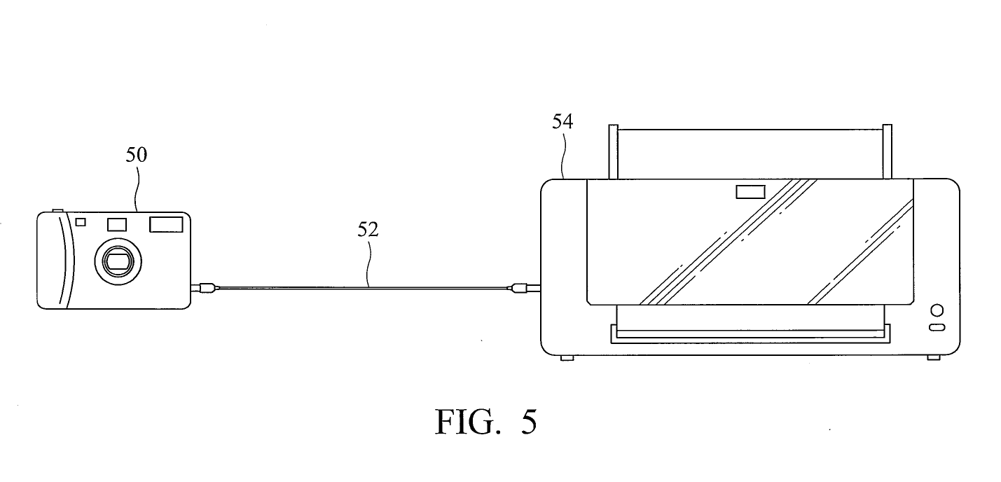

FIG. 5 illustrates an embodiment of color calibration of a digital image. A digital camera 50 and printer 54 are coupled by USB 52, and the coupling conforms to PictBridge protocol.

The digital camera 50 receives information from printer 54 comprising printer type, and determines whether a color calibration conversion matrix of the printer 54 is stored in the digital camera 50. The color calibration conversion matrix comprises conversion matrix coefficients for hue values (RGB values) of the printer 54 and the digital camera 50.

If the color calibration conversion matrix of the printer 54 is stored in the digital camera 50, the color calibration conversion matrix is transmitted to the printer 54. The printer 54 uses the color calibration conversion matrix for printing. If the color calibration conversion matrix of the printer 54 is not stored in the digital camera 50, digital camera 50 converts the Macbeth chart to obtain the color calibration conversion matrix.

The Macbeth chart can be stored in the printer 54 or the digital camera 50. When the Macbeth chart is stored in the digital camera 50, the digital camera 50 transmits the Macbeth chart to the printer 54. The printer 54 prints the Macbeth chart as printed data. The digital camera 50 captures an image of the printed data. The digital camera 50 can be fixed by a fixer when capturing the image.

The image is analyzed by the digital camera 50 to obtain hue values (RGB values) of the printer 54. The color information is obtained according to the hue values of the printer 54 and a hue value of the digital camera 50. The color information is obtained according to the following equation:

$$[ \begin{matrix}R \\ G \\ B\end{matrix} ] = [ \begin{matrix}{a}_{11} & {a}_{12} & {a}_{13} \\ {a}_{21} & {a}_{22} & {a}_{23} \\ {a}_{31} & {a}_{32} & {a}_{33}\end{matrix} ] [ \begin{matrix}{R}_{1} \\ {G}_{1} \\ {B}_{1}\end{matrix} ] .$$

R′ G′ B are hue values of the printer 54, R₁′ G₁′ B₁ are hue values of the digital camera 50, a₁₁˜a₃₃ specify the color information. The obtained color information can be stored in the digital camera 50 or transmitted to the printer 54 for printing.

The methods and system of the invention, or certain aspects or portions thereof, may take the form of program code (i.e., instructions) embodied in tangible media, such as floppy diskettes, CD-ROMS, hard drives, or any other machine-readable storage medium, wherein, when the program code is loaded into and executed by a machine, such as a computer, the machine becomes an apparatus for practicing the invention. The methods and apparatus of the present invention may also be embodied in the form of program code transmitted over some transmission medium, such as electrical wiring or cabling, through fiber optics, or via any other form of transmission, wherein, when the program code is received and loaded into and executed by a machine, such as a computer, the machine becomes an apparatus for practicing the invention. When implemented on a general-purpose processor, the program code combines with the processor to provide a unique apparatus that operates analogously to specific logic circuits.

While the invention has been described by way of example and in terms of preferred embodiment, it is to be understood that the invention is not limited thereto. To the contrary, it is intended to cover various calibrations and similar arrangements (as would be apparent to those skilled in the art). Therefore, the scope of the appended claims should be accorded the broadest interpretation so as to encompass all such calibrations and similar arrangements.

What is claimed is:

1. A method for color calibration of a digital image, implemented in a digital image capture device, comprising:
receiving identification information of a printer, wherein the printer is coupled to the digital image capture device;
determining whether color information of the printer is stored in the digital image capture device;
transmitting the color information to the printer if the color information of the printer is stored in the digital image capture device; and
converting hue value calibration data to obtain the color information if color information of the printer is not stored in the digital image capture device.

2. The method of claim 1, further directing the printer to print using the color information.

3. The method of claim 1, further storing the color information in the digital image capture device.

4. The method of claim 1, wherein the digital image capture device and the printer are coupled according to PictBridge protocol.

5. The method of claim 1, wherein the identification information specifies the printer type.

6. The method of claim 1, wherein the color information is a color calibration conversion matrix.

7. The method of claim 1, wherein the hue value calibration data is a Macbeth chart.

8. The method of claim 1, wherein the conversion step further comprises:
directing the printer to print the hue value calibration data as printed data;
directing the digital image capture device to capture an image of the printed data;
analyzing the image to obtain a hue value of the printer; and
obtaining the color information according to the hue value of the printer and a hue value of the digital image capture device.

9. The method of claim 8, wherein the color information is obtained according to the following equation:
$$[ \begin{matrix}R \\ G \\ B\end{matrix} ] = [ \begin{matrix}{a}_{11} & {a}_{12} & {a}_{13} \\ {a}_{21} & {a}_{22} & {a}_{23} \\ {a}_{31} & {a}_{32} & {a}_{33}\end{matrix} ] [ \begin{matrix}{R}_{1} \\ {G}_{1} \\ {B}_{1}\end{matrix} ] ,$$
wherein R′ G′ B are hue values of the printer, R₁′ G₁′ B₁ are hue values of the digital image capture device, a₁₁˜a₃₃ specify the color information.

11. The method of claim 8, wherein when the hue value calibration data is stored in the digital image capture device, the digital image capture device transmits the hue value calibration data to the printer before the printer prints the hue value calibration data.

12. A storage medium for storing a computer program providing a method for color calibration of a digital image of claim 1.

13. A system for color calibration of a digital image, implemented in a digital image capture device, comprising:
a receiving module, receiving identification information of a printer, wherein the printer is coupled to the digital image capture device;
an identifying module, coupling to the receiving module, determining whether color information of the printer is stored in the digital image capture device;
a transmission module, coupling to the identifying module, transmitting the color information to the printer if the color information of the printer is stored in the digital image capture device; and
a converting module, coupling to the identifying module, converting hue value calibration data to obtain the color information if color information of the printer is not stored in the digital image capture device.

14. The system of claim 13, further comprising a printing module, coupling to the transmission module, printing using the color information.

15. The system of claim 13, further comprising a storage module, coupling to the converting module, storing the color information in the digital image capture device.

16. The system of claim 13, wherein the digital image capture device and the printer are coupled according to PictBridge protocol.

17. The system of claim 13, wherein the identification information specifies the printer type.

18. The system of claim 13, wherein the color information is a color calibration conversion matrix.

19. The system of claim 13, wherein the hue value calibration data is a Macbeth chart.

20. The system of claim 13, wherein the converting module further:
directing the digital image capture device to capture printed data as an image, wherein the printed data is obtained by using the printer to print the hue value calibration data;
analyzing the image to obtain a hue value of the printer; and
obtaining the color information according to the hue value of the printer and a hue value of the digital image capture device.

21. The system of claim 20, wherein the converting module further obtains the color information according to the following equation:
$$[ \begin{matrix}R \\ G \\ B\end{matrix} ] = [ \begin{matrix}{a}_{11} & {a}_{12} & {a}_{13} \\ {a}_{21} & {a}_{22} & {a}_{23} \\ {a}_{31} & {a}_{32} & {a}_{33}\end{matrix} ] [ \begin{matrix}{R}_{1} \\ {G}_{1} \\ {B}_{1}\end{matrix} ] ,$$
wherein R′ G′ B are hue values of the printer, R₁′ G₁′ B₁ are hue values of the digital image capture device, a₁₁˜a₃₃ specify the color information.

22. The system of claim 20, wherein the hue value calibration data is stored in the printer or the digital image capture device.

23. The system of claim 20, when the hue value calibration data is stored in the digital image capture device, the digital image capture device transmits the hue value calibration data to the printer before the printer prints the hue value calibration data.
